(19) United States
(12) Patent Application Publication
(10) Pub. No.: US 2011/0223519 A1
(43) Pub. Date: Sep. 15, 2011

(54) SOLID OXIDE FUEL CELL AND METHOD OF PREPARING THE SAME

(75) Inventors: Sang-kyun KANG, Seoul (KR); Tae-young Kim, Seoul (KR); Pil-won Heo, Yongin-si (KR); Jin-su Ha, Seoul (KR)

(73) Assignee: Samsung Electronics Co., Ltd., Suwon-si (KR)

(21) Appl. No.: 12/857,794

(22) Filed: Aug. 17, 2010

(30) Foreign Application Priority Data
Mar. 10, 2010 (KR) 10-2010-0021380

(51) Int. Cl. H01M 8/10; H01M 8/00; C23C 14/34

(52) U.S. Cl. 429/483; 427/115; 427/585; 427/596; 204/192.1

(57) ABSTRACT

A solid oxide fuel cell includes a membrane electrode assembly including an anode, a cathode, and a solid oxide electrolyte membrane disposed between the anode and the cathode; and a porous conductive support disposed at one surface or both surfaces of the membrane electrode assembly. Both the membrane electrode assembly and the porous conductive support have an uneven structure, and are coupled to each other in a male and female coupling manner.

### CROSS-REFERENCE TO RELATED APPLICATION

This application claims the benefit of Korean Application No. 10-2010-0021380, filed Mar. 10, 2010 in the Korean Intellectual Property Office, the disclosure of which is incorporated herein by reference.

### BACKGROUND

1. Field

Aspects of the present disclosure relate to a solid oxide fuel cell and a method of preparing the same.

2. Description of the Related Art

As one of the alternative energy sources, fuel cells can be classified into polymer electrolyte membrane fuel cells (PEMFCs), phosphoric acid fuel cells (PAFCs), molten carbonate fuel cells (MCFCs), and solid oxide fuel cells (SOFCs) according to the types of electrolyte. SOFCs include a solid oxide having ionic conductivity as an electrolyte. SOFCs have high efficiency, excellent durability, and relatively low manufacturing costs, and use a variety of fuels.

The power density of the SOFCs is proportionate to an areal density of the SOFCs. The areal density is obtained by dividing a real reaction area by an apparent area (e.g., an area of a level surface of a fuel cell). Thus, in order to increase the reaction area, an uneven structure may be formed to be perpendicular to the plane of a membrane electrode assembly (MEA).

An areal density of a MEA having an uneven structure formed to be perpendicular to the MEA is generally proportionate to an aspect ratio of the uneven structure (e.g., height/width of the uneven structure). As the aspect ratio increases according to the increase in height of the uneven structure, the resistance increases according to the increase in electron transfer distance. So, it is preferred that the increase of the area density is induced from the decrease in width of the uneven structure. Meanwhile, as the aspect ratio increased according to the decrease in width of the uneven structure, the thickness of the MEA need to be reduced. As the thickness of the MEA decreases, the areal density may increase, but a large MEA may not be manufactured due to reduced mechanical strength.

Thus, there is a need to develop a fuel cell having a large area with increased mechanical strength in addition to high areal density.

### SUMMARY

According to an aspect of the invention, there is provided is a solid oxide fuel cell.

According to an aspect of the invention, there is provided is a method of preparing the solid oxide fuel cell.

According to an aspect of the present invention, a solid oxide fuel cell includes: a membrane electrode assembly comprising: an anode; a cathode; and a solid oxide electrolyte membrane disposed between the anode and the cathode; and a porous conductive support disposed at one surface or both surfaces of the membrane electrode assembly, wherein both the membrane electrode assembly and the porous conductive support, having an uneven structure, are coupled to each other in a male and female coupling manner.

According to another aspect of the present invention, a method of preparing a solid oxide fuel cell includes: depositing a solid oxide electrolyte membrane on a substrate having an uneven structure; depositing a thin-film first electrode on one surface of the solid oxide electrolyte membrane; forming a first porous conductive support on the thin-film first electrode; removing the substrate; and depositing a thin-film second electrode on the other surface of the solid oxide electrolyte membrane from which the substrate is removed.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1A shows a substrate according to an embodiment of the present invention;

FIG. 1B is a cross-sectional view of the substrate of FIG. 1; and

FIGS. 2A to 2I are schematic cross-sectional views for describing a method of preparing a unit cell of a fuel cell according to embodiments of the present invention.

### DETAILED DESCRIPTION

Reference will now be made in detail to the present embodiments of the present invention, examples of which are illustrated in the accompanying drawings, wherein like reference numerals refer to the like elements throughout. The embodiments are described below in order to explain the present invention by referring to the figures.

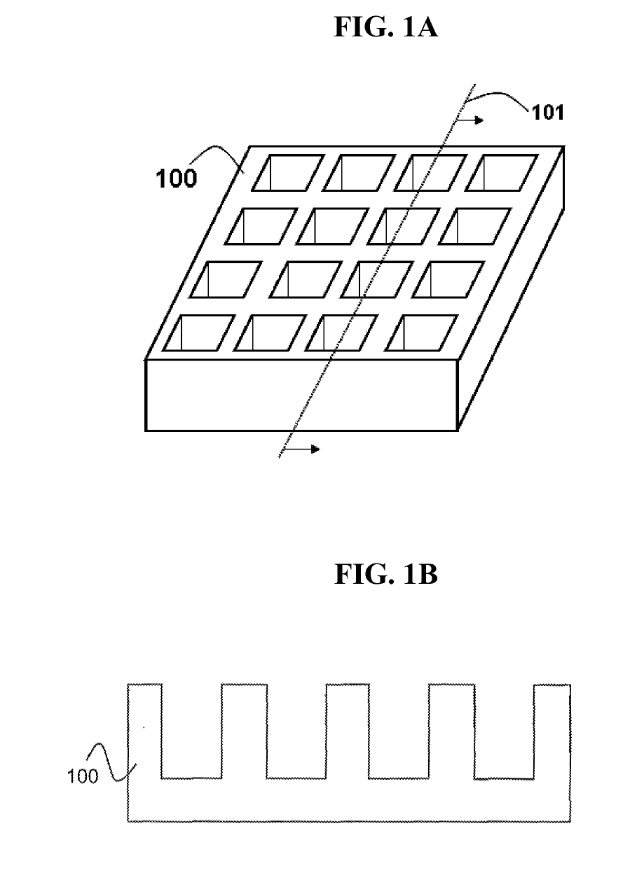

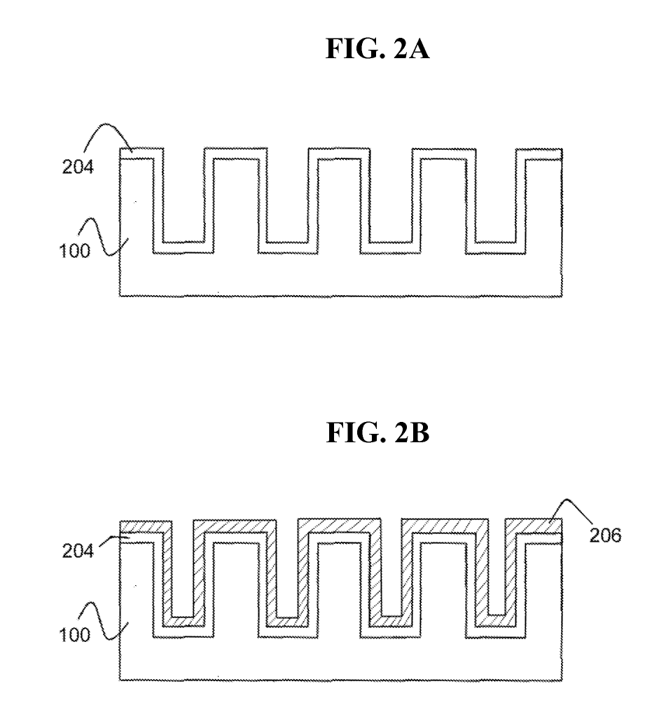

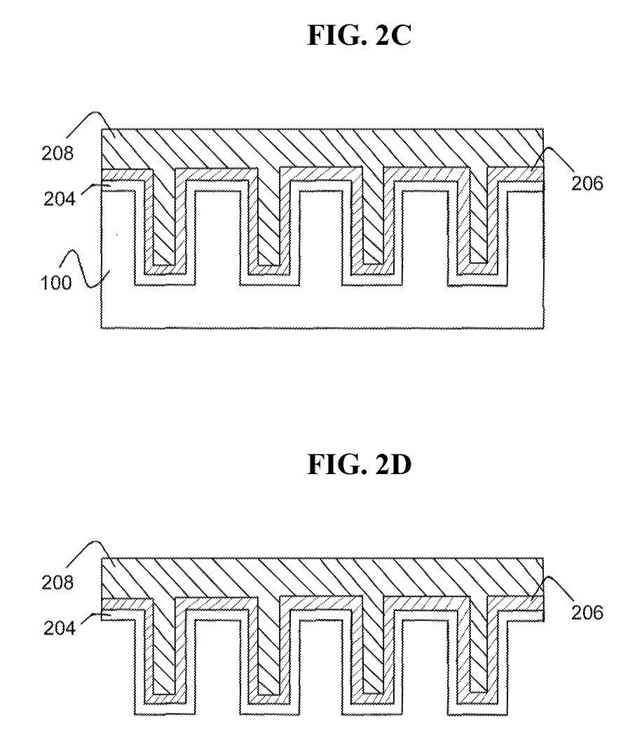

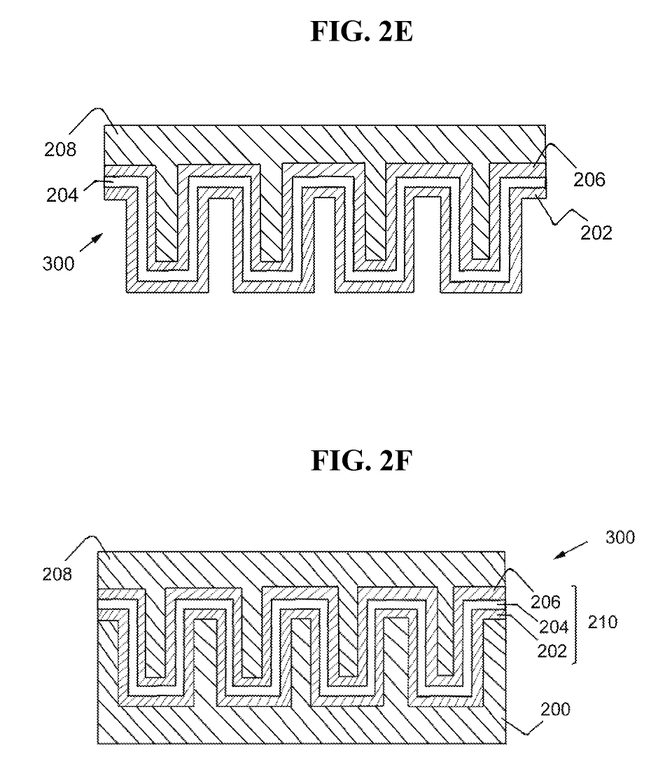

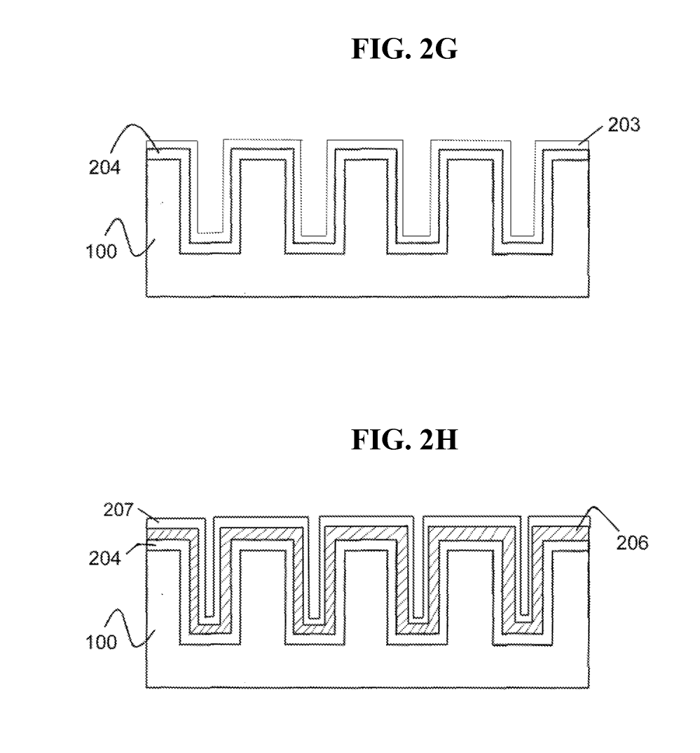

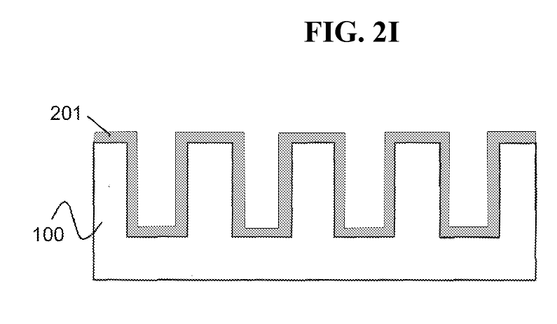

Hereinafter, a solid oxide fuel cell and a method of preparing the solid oxide fuel cell according to one or more embodiments of the present invention will be described in more detail in relation to FIGS. 1A through 2F. A solid oxide fuel cell according to an embodiment of the present invention includes a membrane electrode assembly (MEA) 210 including an anode 202 or 206, a cathode 206 or 202, and a solid oxide electrolyte membrane 204 disposed between the anode and the cathode 202, 206; and a porous conductive support 200 disposed at one surface or both surfaces of the MEA 210 and/or 208. The MEA 210 and the porous conductive support 200 and/or 208 have an uneven structure, and are coupled to each other in a male and female coupling manner.

For example, the MEA 210 has an uneven structure including at least one protrusion and at least one recession on one surface or both surfaces of the MEA 210. The porous conductive support 200 and/or 208 has a corresponding uneven structure on one surface that contacts with the MEA 210 such that the porous conductive support 200 is coupled to the MEA 210 in a male and female coupling manner.

For example, as shown in FIG. 2F, both surfaces of a MEA 210 included in a unit cell 300 of the fuel cell have three-dimensional uneven structures including at least one protrusion and at least one recession. Therefore, the reaction area increases when compared to a flat MEA 210 which lacks the uneven structure. As a result, the MEA 210 has an increased areal density, so that power density of the fuel cell may be improved. The MEA 210 of the solid oxide fuel cell may have an areal density equal to or greater than 8, wherein the areal density is calculated according to Equation 1 below.

Areal density=reaction area/apparent area Equation 1

As used in Equation 1, the reaction area is the total area available for reaction, which would include those areas which are non-horizontal as well as the horizontal areas in FIG. 2F. The apparent area includes only the two-dimensional area covered by the reaction area, which in FIG. 2F would be the length and width of the MEA 210 not accounting for the non-horizontal areas. For example, the areal density may be in the range of about 8 to about 400. For example, the areal density may be in the range of about 19 to about 400. For example, the areal density may be in the range of about 37 to about 400. However, the invention is not limited thereto.

In addition, as shown in FIGS. 2E and 2F, the unit cell 300 of the fuel cell may have mechanical durability since the porous conductive supports 200 and 208 having the uneven structure that is coupled to the uneven structure of the MEA 210 in a male and female coupling manner. Thus, a large-sized fuel cell may be manufactured.

In the solid oxide fuel cell, the apparent area of the MEA 210 may be equal to or greater than 1 cm². For example, the apparent area may be in the range of about 1 to about 1000 cm². For example, the apparent area may be in the range of about 10 to about 100 cm².

The uneven structure may include protrusions and recessions forming periodic lattices. The lattice may be hexagonal lattice, tetragonal lattice, or cubic lattice. However, the structure is not specifically limited and need not be rectangular as shown. Instead, the uneven structure may be curvilinear in aspects of the invention. Further, while shown as being regularly spaced and having a same height, the protrusions need not be regular spaced in all aspects of the invention.

The height of the uneven structure is a distance between the protrusion and the recession and may be substantially uniformly maintained in the MEA 210. The protrusions and the recessions may be aligned in opposite directions. However, it is understood that the heights and widths need not be uniform in all aspects.

For example, as shown in FIG. 2F, the uneven structure of the MEA 210 includes at least one protrusion (or first protrusion) which is formed by recessing the surface of the anode 202 or 206 of the MEA 210 toward the cathode 206 or 202 to protrude the surface of the cathode 206 or 202. Further, the at least one recession (or second protrusion) is formed by recessing the surface of the cathode 206 or 202 of the MEA 210 toward the anode 202 or 206 to protrude the surface of the anode 202 or 206. Accordingly, the distance between the protrusion and the recession may be substantially uniformly maintained within the MEA 210. Due to the uneven structure having the protrusions and the recessions, the areal density of the MEA 210 may be improved. For example, the areal density of the MEA 210 may be improved as the distance between the protrusion and the recession increases. While described in terms of being formed by protruding, it is understood that other mechanisms and methods can be used to form the protrusions and recessions.

At least one of the protrusion and recession may have a tubular shape having one end closed. For example, the protrusion and/or recession may have a microtube or nanotube having one end closed. The cross-section of the microtube or nanotube may have various shapes such as circular, hexagonal, square, and rectangular shapes.

The height of the protrusion and/or the depth of the recession may be in the range of about 0.5 μm to about 40 μm. For example, the height of the protrusion and/or the depth of the recession may be in the range of about 5 μm to about 40 μm. For example, the height of the protrusion and/or the depth of the recession may be in the range of about 5 μm to about 25 μm. For example, the height of the protrusion and/or the depth of the recession may be in the range of about 5 μm to about 20 μm. For example, the height of the protrusion and/or the depth of the recession may be in the range of about 5 μm to about 10 μm.

The width (e.g., diameter) of the protrusion and/or the recession may be in the range of about 0.2 μm to about 25 μm. For example, the width of the protrusion and/or the recession may be in the range of about 1 μm to about 25 μm. For example, the width of the protrusion and/or the recession may be in the range of about 1 μm to about 20 μm. For example, the width of the protrusion and/or the recession may be in the range of about 1 μm to about 10 μm. For example, the width of the protrusion and/or the recession may be in the range of about 1 μm to about 5 μm.

The aspect ratio between the height or depth and the width of the protrusion and/or the recession may be equal to or greater than 2:1. For example, the aspect ratio of the protrusion and/or the recession may be in the range of about 2:1 to about 100:1. For example, the aspect ratio of the protrusion and/or the recession may be in the range of about 5:1 to about 100:1. For example, the aspect ratio of the protrusion and/or the recession may be in the range of about 10:1 to about 100:1.

While not required in all aspects, the MEA 210 may further include a protective layer 203 disposed on one surface of a solid oxide electrolyte membrane 204 (e.g., thin-film solid oxide electrolyte). For example, as shown in FIG. 2G, the protective layer 203 may be disposed on at least one surface of the solid oxide electrolyte membrane 204, wherein the protective layer blocks the reaction between the solid oxide electrolyte and compounds such as CO₂ which are generated during the operation of the fuel cell and degrade performance of the solid oxide electrolyte.

Examples of the protective layer 203 may include at least one selected from the group consisting of palladium (Pd). Pd alloys, RuO₂, WO₃, vanadium (V), Yttrium Stabilized Zirconia (YSZ), and zeolite. The YSZ may have grains with micrometer or smaller dimensions.

While not required in all aspects, the anode and cathode 202,206 of the solid oxide fuel cell may be each independently a porous thin film or non-porous thin film. That is, the anode and cathode 202 or 206 may be porous thin films. The pore size of the porous thin-film anode or cathode 202 or 206 may be in the range of about 5 nm to about 500 nm, but is not limited thereto. The pore size may vary if desired.

While not required in all aspects, the anode and cathode 202 and 206 may be an oxygen ion transmissive thin film or proton transmissive thin film. Examples of the anode and cathode 202, 206 may each independently include at least one selected from the group consisting of: metal such as platinum (Pt), nickel (Ni), palladium (Pd), and silver (Ag); perovskite doped with at least one selected from the group consisting of lanthanum (La), strontium (Sr), barium (Ba), and cobalt (Co); oxygen ion conductor such as zirconia doped with yttrium (Y) or scandium (Sc) and ceria doped with at least one selected from the group consisting of gadolinium (Gd), samarium (Sm), lanthanum (La), ytterbium (Yb), and neodymium (Nd); proton conductive metal such as Pd. Pd—Ag alloy, and vanadium (V); zeolite; lanthanum strontium manganate (LSM) doped with lanthanum (La) or calcium (Ca); and lanthanum strontium cobalt ferrite (LSCF), but are not limited thereto. Any material for an anode or cathode 202 or 206 commonly used in the art may also be used.

While not required in all aspects, the anode and cathode 202,206 may each independently have a thickness equal to or less than 1 μm. For example, the anode and cathode may each independently have a thickness in the range of about 5 nm to about 1 μm. For example, the anode and cathode 202,206 may each independently have a thickness in the range of about 5 nm to about 500 nm. For example, the anode and cathode 202,206 may each independently have a thickness in the range of about 5 nm to about 200 nm.

While not required in all aspects, a catalyst 207 may further be disposed on one surface of the anode and cathode 202,206 included in the MEA 210 of the solid oxide fuel cell. For example, as shown in FIG. 2H, a catalyst 207 may further be disposed on the surface of the cathode and anode 202,206. For example, a catalyst layer 207 including the catalyst may be disposed between the cathode 202 or 206 and the porous conductive support 200 or 208 and/or between the anode 202 or 206 and the porous conductive support 200 or 208. The catalyst 207 may have particles with sub-micron scale. For example, the catalyst 207 may be nano-sized particles.

Examples of the catalyst 207 may include at least one selected from the group consisting of: metal catalyst such as platinum (Pt), ruthenium (Ru), nickel (Ni), palladium (Pd), gold (Au), and silver (Ag); an oxide catalyst such as La₁₋ₓSrₓMnO₃ (0<x<1), La₁₋ₓSrₓCoO₃ (0<x<1), and La₁₋ₓSrₓCO_{y}Fe_{1-y}O₃ (0<x<1, 0<y<1); and alloys thereof, but is not limited thereto. Any catalyst that is commonly used in the art may also be used.

While not required in all aspects, the thin-film solid oxide electrolyte membrane 204 of the solid oxide fuel cell may include at least one selected from the group consisting of an oxygen ion conductive solid oxide; a proton conductive solid oxide, and an oxygen ion-proton conductive solid oxide, but is not limited thereto. Any material that is commonly used in the art may also be used.

For example, the solid oxide electrolyte membrane may include doped fluorite such as doped cerium oxide, doped bismuth oxide, perovskite, or the like. For example, the oxygen ion conductive solid oxide may include at least one selected from the group consisting of zirconia doped with yttrium (Y) or scandium (Sc); ceria doped with at least one selected from the group consisting of gadolinium (Gd), samarium (Sm), lanthanum (La), ytterbium (Yb), and neodymium (Nd); and lanthanum gallate doped with strontium (Sr) or magnesium (Mg). For example, the proton conductive solid oxide may include at least one selected from the group consisting of: zeolite substituted with proton; β-alumina; and barium zirconate doped with a bivalent or trivalent cation, barium cerate doped with a bivalent or trivalent cation, strontium cerate doped with a bivalent or trivalent cation, or strontium zirconate doped with a bivalent or trivalent cation. For example, the oxygen ion-proton conductive solid oxide may include at least one selected from the group consisting of BaZrO₃, BaCeO₃, SrZrO₃, or SrCeO₃ doped with a trivalent element such as Y or Yb; and Ba₂In₂O₅ doped with the cation of one element selected from the group consisting of vanadium (V), niobium (Nb), tantalum (Ta), molybdenum (Mo), and tungsten (W).

While not required in all aspects, the thickness of the solid oxide electrolyte membrane 204 may be equal to or less than 2 μm and greater than zero. For example, the thickness of the solid oxide electrolyte membrane 204 may be in the range of about 5 nm to about 2 μm. For example, the thickness of the solid oxide electrolyte membrane may be in the range of about 5 nm to about 500 nm. For example, the thickness of the solid oxide electrolyte membrane may be in the range of about 5 nm to about 200 nm.

While not required in all aspects, the porous conductive support 200 or 208 of the solid oxide fuel cell may be selected from the group consisting of metal, conductive ceramic, or any mixture thereof. For example, the porous conductive support may include at least one selected from the group consisting of nickel (Ni), YSZ, alumina (Al₂O₃), palladium (Pd), and lanthanum chromite (LaCrO₃), but is not limited thereto. Any material for a conductive support that is commonly used in the art may also be used.

In order to support the MEA 210, the porous conductive support 200 or 208 has uniform mechanical strength. The mechanical strength of the porous conductive support 200 or 208 may be sufficient for sustaining the MEA 210 having a large size with an apparent area of 1 cm².

The pore size of the porous conductive support 200 or 208 may be in the range of about 10 nm to about 1000 nm, but the invention is not limited thereto. The pore size may vary if desired.

A method of preparing a solid oxide fuel cell according to another embodiment of the present invention includes: depositing a solid oxide electrolyte membrane 204 on a substrate 100 having an uneven structure; depositing a thin-film first electrode 206 on one surface of the solid oxide electrolyte membrane 204; forming a first porous conductive support 208 on the thin-film first electrode 206; removing the substrate 100; and depositing a thin-film second electrode 202 on the other surface of the solid oxide electrolyte membrane 204 from which the substrate 200 is removed.

A porous conductive support 200 is disposed on one surface or both surfaces of the MEA 210 including: a first electrode 202 or 206; a second electrode 206 or 202; and a solid oxide electrolyte membrane 204 disposed between the first electrode and the second electrode 202,206. The MEA 210 and the porous conductive support 200,208 may respectively have uneven structures that are coupled to each other in a male and female coupling manner. For example, the MEA 210 has an uneven structure including at least one protrusion and at least one recession on one surface or both surfaces of the MEA 210, and the porous conductive support 200,208 has an uneven structure on one surface that contacts with the MEA 210 such that the porous conductive support is coupled to the MEA 210 in a male and female coupling manner. One of the first and second electrodes 202,206 may be anode, and the other may be cathode.

A method of preparing the solid oxide fuel cell will be described in more detail with reference to FIGS. 1A to 2F. As shown in FIGS. 1A and 1B, the substrate 100 having an uneven structure is prepared. FIG. 1B is a cross-sectional view of the substrate 100 of FIG. 1A taken along dotted lines 101 in the arrow direction. As shown in FIGS. 2A to 2E, the solid oxide electrolyte membrane 204 is deposited on the substrate 100. The thin-film first electrode 206 is deposited on the solid oxide electrolyte membrane 204. The first porous conductive support 208 is formed on the thin-film first electrode 206. The substrate 100 is removed, such as by etching, or the like. Then, a thin-film second electrode 202 is deposited on the other surface of the solid oxide electrolyte membrane 204 exposed by removing the substrate 100 to prepare a unit cell 300 of the fuel cell.

As shown in FIG. 2F, the method further includes forming the second porous conductive support 200 on the thin-film second electrode 202 after depositing the thin-film second electrode 202. However, it is understood that the second porous conductive surface 200 need not be used in all aspects, such that the operation shown in FIG. 2F need not be used.

As shown in FIG. 2F, the MEA 210 including the first electrode 206, the second electrode 202, and the solid oxide electrolyte membrane 204 may have a three-dimensional uneven structure having at least one protrusion and at least one recession formed on both surfaces thereof. The first porous conductive support 208 and the second porous conductive support 200 may have an uneven structure that is coupled to the uneven structure of the MEA 210 in a male and female coupling manner on one surface thereof.

In addition, the uneven structure of the MEA 210 includes at least one protrusion (or first protrusion) formed by recessing the surface of the anode 202 or 206 of the MEA 210 toward the cathode 206 or 202 to protrude the surface of the cathode 206 or 202 and at least one recession (or second protrusion) that protrudes in the opposite direction of the first protrusion. For example, the recession may be formed by recessing the surface of the cathode 206 or 202 of the MEA 210 toward the anode 202 or 206 to protrude the surface of the anode 202 or 206.

In addition, the height of the uneven structure is a distance between the protrusion and the recession. The height may be substantially uniformly maintained in the MEA 210. As the distance increases, the areal density of the MEA 210 increases. Specifically, since the first porous conductive support 208 acts as a mechanical supporter of the MEA 210 during the preparation of the MEA 210, a free standing step of the MEA 210 may be avoided. Thus, a large-sized MEA 210 may be manufactured (210). As a result, a large-sized unit cell 300 of the fuel cell may be manufactured.

According to the shown embodiment of method, the first electrode 206, the second electrode 202, the solid oxide electrolyte 204, and the first porous conductive support 208 may be each independently deposited using at least one method selected from the group consisting of sputtering, chemical vapor deposition, physical vapor deposition, atomic layer deposition, plating, pulsed laser deposition, molecular beam epitaxy, and vacuum deposition, but the method is not limited thereto. Any method for forming a thin film commonly used in the art may also be used. The plating can include electroplating and electroless plating according to aspects of the invention, but the invention is not limited thereto.

In the etching process of the substrate 100, any etching method that is commonly used in the art may be used. For example, a wet etching, a dry etching, or the like may be used. For example, if the substrate 100 is a silicon substrate, a KOH aqueous solution may be used.

Even though not shown herein, the method may further include depositing a catalyst on the first electrode 206 and the second electrode 202. The catalyst may be nano-sized particles. The catalyst may be deposited using at least one method selected from the group consisting of sputtering, chemical vapor deposition, physical vapor deposition, atomic layer deposition, plating, pulsed laser deposition, molecular beam epitaxy, and vacuum deposition, but the method is not limited thereto. Any method for forming a thin film commonly used in the art may also be used. The plating includes electroplating and electroless plating.

As shown in FIG. 2I, the method may further include depositing an etch blocking layer 201 on the substrate 100 before depositing the solid oxide electrolyte membrane 204 on the substrate 100. The etch blocking layer 201 may prevent the solid oxide electrolyte membrane 204 from being damaged during etching the substrate 100. The etch blocking layer may 201 include at least one selected from the group consisting of SiO₂; Si₃N₄; and metal thin film such as Cr, Au, Pd, Pd—Ag, V, and Pt.

As shown in FIG. 2G, the method may further include depositing a protective layer 203 on the substrate 100 before depositing the solid oxide electrolyte membrane 204. The protective layer 203 blocks compounds such as CO₂ which are generated during the operation of the fuel cell and degrade performance of the solid oxide electrolyte 204. The protective layer 203 may include at least one selected from the group consisting of Pd, Pd alloys, RuO₂, WO₃, V, Yttrium Stabilized Zirconia (YSZ), and zeolite. The YSZ may have grains with micrometer or smaller dimensions. The etch blocking layer 201 and the protective layer 203 may be formed as a single layer.

As described above, according to the one or more of the above embodiments of the present invention, a large-sized solid oxide fuel cell with high power density may be prepared since the MEA having high areal density is coupled to the porous conductive support via the uneven structure in a male and female coupling manner.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A solid oxide fuel cell comprising:
a membrane electrode assembly comprising: an anode; a cathode; and a solid oxide electrolyte membrane disposed between the anode and the cathode; and
a porous conductive support disposed at one surface or both surfaces of the membrane electrode assembly,
wherein the membrane electrode assembly and the porous conductive support each have an uneven structure such that the membrane electrode assembly is coupled to the porous conductive support in a male and female coupling manner.

2. The solid oxide fuel cell of claim 1, wherein:
the membrane electrode assembly has an areal density equal to or greater than 8,
the areal density is calculated according to Equation 1 below:
Areal density=reaction area/apparent area, Equation 1
the reaction area is a total area of the membrane electrode assembly available for reaction, and
the apparent area includes only a two-dimensional area covered by the reaction area.

3. The solid oxide fuel cell of claim 2, wherein the apparent area of the membrane electrode assembly is equal to or greater than 1 cm².

4. The solid oxide fuel cell of claim 1, wherein the uneven structure has protrusions and recessions forming periodic lattices.

5. The solid oxide fuel cell of claim 4, wherein the lattices comprises one of more hexagonal lattices, tetragonal lattices, and/or cubic lattices.

6. The solid oxide fuel cell of claim 4, wherein at least one of the protrusion and recession has a tubular shape having one end closed.

7. The solid oxide fuel cell of claim 4, wherein at least one of a height of the protrusion and a depth of the recession is in the range of about 0.5 μm to about 40 μm.

8. The solid oxide fuel cell of claim 4, wherein a width of at least one of the protrusion and the recession is in the range of about 0.2 μm to about 25 μm.

9. The solid oxide fuel cell of claim 4, wherein an aspect ratio of at least one of the protrusion and the recession is equal to or greater than 2:1.

10. The solid oxide fuel cell of claim 1, wherein the membrane electrode assembly further comprises a protective layer disposed on one or both surfaces of the solid oxide electrolyte membrane.

11. The solid oxide fuel cell of claim 10, wherein the protective layer comprises at least one selected from the group consisting of Pd, Pd alloys, RuO₂, WO₃, V, Yttrium Stabilized Zirconia (YSZ), and zeolite.

12. The solid oxide fuel cell of claim 1, wherein the anode and cathode each independently comprises at least one selected from the group consisting of: platinum (Pt); nickel (Ni); palladium (Pd); silver (Ag); perovskite doped with at least one selected from the group consisting of lanthanum (La), strontium (Sr), barium (Ba), and cobalt (Co); zirconia doped with yttrium (Y) or scandium (Sc); ceria doped with at least one selected from the group consisting of gadolinium (Gd), samarium (Sm), lanthanum (La), ytterbium (Yb), and neodymium (Nd); at least one proton conductive metal selected from the group consisting of Pd, Pd—Ag alloy, and vanadium (V); zeolite; lanthanum strontium manganate (LSM) doped with lanthanum (La) or calcium (Ca); and lanthanum strontium cobalt ferrite (LSCF).

13. The solid oxide fuel cell of claim 1, wherein the anode and cathode each independently have a thickness equal to or less than 1 μm.

14. The solid oxide fuel cell of claim 1, wherein a catalyst is disposed on one surface of the anode and cathode.

15. The solid oxide fuel cell of claim 14, wherein the catalyst comprises at least one selected from the group consisting of: at least one metal catalyst selected from the group consisting of platinum (Pt), ruthenium (Ru), nickel (Ni), palladium (Pd), gold (Au), and silver (Ag); at least one oxide catalyst selected from the group consisting of La₁₋ₓSrₓMnO₃ (0<x<1), La₁₋ₓSrₓCoO₃ (0<x<1), and La₁₋ₓSrₓCO_{y}Fe_{1-y}O₃ (0<x<1, 0<y<1); and alloys thereof.

16. The solid oxide fuel cell of claim 1, wherein the solid oxide electrolyte membrane comprises at least one selected from the group consisting of an oxygen ion conductive solid oxide; a proton conductive solid oxide, and an oxygen ion-proton conductive solid oxide.

17. The solid oxide fuel cell of claim 16, wherein the solid oxide electrolyte membrane comprises the oxygen ion conductive solid oxide which comprises at least one selected from the group consisting of zirconia doped with yttrium (Y) or scandium (Sc); ceria doped with at least one selected from the group consisting of gadolinium (Gd), samarium (Sm), lanthanum (La), ytterbium (Yb), and neodymium (Nd); and lanthanum gallate doped with strontium (Sr) or magnesium (Mg).

18. The solid oxide fuel cell of claim 16, wherein the solid oxide electrolyte membrane comprises the proton conductive solid oxide which comprises at least one selected from the group consisting of: zeolite substituted with proton; β-alumina; and barium zirconate, barium cerate, strontium cerate, or strontium zirconate doped with a bivalent or trivalent cation.

19. The solid oxide fuel cell of claim 16, wherein the solid oxide electrolyte membrane comprises the oxygen ion-proton conductive solid oxide which comprises at least one selected from the group consisting of BaZrO₃, BaCeO₃, SrZrO₃, or SrCeO₃ doped with trivalent Y or Yb; and Ba₂In₂O₅ doped with the cation of one element selected from the group consisting of vanadium (V), niobium (Nb), tantalum (Ta), molybdenum (Mo), and tungsten (W).

20. The solid oxide fuel cell of claim 1, wherein a thickness of the solid oxide electrolyte membrane is greater than zero and equal to or less than 2 μm.

21. The solid oxide fuel cell of claim 1, wherein the porous conductive support comprises metal, conductive ceramic, or any mixture thereof.

22. The solid oxide fuel cell of claim 1, wherein the porous conductive support has a pore size in the range of about 10 nm to about 1000 nm.

23. A method of preparing a solid oxide fuel cell of claim 1, the method comprising:
depositing the solid oxide electrolyte membrane on a substrate having the uneven structure;
depositing a thin-film first electrode on one surface of the deposited solid oxide electrolyte membrane;
forming the porous conductive support on the deposited thin-film first electrode;
removing the substrate; and
depositing a thin-film second electrode on the other surface of the solid oxide electrolyte membrane from which the substrate is removed.

24. The method of claim 23, further comprising forming another porous conductive support on the deposited thin-film second electrode after depositing the thin-film second electrode.

25. The method of claim 23, wherein the thin-film first electrode, the thin-film second electrode, the solid oxide electrolyte membrane, and the porous conductive support are each independently deposited using at least one method selected from the group consisting of sputtering, chemical vapor deposition, physical vapor deposition, atomic layer deposition, plating, pulsed laser deposition, molecular beam epitaxy, and vacuum deposition.

26. The method of claim 23, further comprising depositing a catalyst on the first thin-film electrode and the thin-film second electrode.

27. The method of claim 26, wherein the catalyst is deposited using at least one method selected from the group consisting of sputtering, chemical vapor deposition, physical vapor deposition, atomic layer deposition, plating, pulsed laser deposition, molecular beam epitaxy, and vacuum deposition.

28. The method of claim 23, further comprising depositing an etch blocking layer on the substrate before depositing the solid oxide electrolyte membrane.

29. The method of claim 23, further comprising depositing a protective layer on the substrate before depositing the solid oxide electrolyte membrane.
